(19) United States
(12) Patent Application Publication
(10) Pub. No.: US 2026/0009752 A1
(43) Pub. Date: Jan. 8, 2026

(54) ALIGNED NUCLEAR MAGNETIC RESONANCE RESULTS

(71) Applicant: 4IR Solutions Ltd., Or-Akiva (IL)

(72) Inventor: Tal Cohen, Herzliya (IL)

(73) Assignee: 4IR Solutions Ltd., Or-Akiva (IL)

(21) Appl. No.: 18/764,057

(22) Filed: Jul. 3, 2024

(51) Int. Cl. G01N 24/08; G01R 33/30; G01R 33/31; G01V 3/14

(52) U.S. Cl. CPC G01N 24/08; G01R 33/302; G01R 33/31; G01V 3/14

(57) ABSTRACT

An NMR device that includes (i) a first fluid conduit that includes a measurement region and is configured to convey fluid, (ii) an NMR measurement unit that is configured to perform an NMR measurement of the fluid within the measurement region; wherein the NMR measurement unit comprises a permanent magnet; and (iii) a temperature control unit that is configured to thermally shield the permanent magnet, during the NMR measurement, from a temperature of the fluid within measurement region.

### BACKGROUND OF THE INVENTION

Nuclear magnetic resonance (NMR) is a physical phenomenon in which nuclei in a strong constant magnetic field are perturbed by a weak oscillating magnetic field (in the near field) and respond by producing an electromagnetic signal with a frequency characteristic of the magnetic field at the nucleus.

This process occurs near resonance, when the oscillation frequency matches the intrinsic frequency of the nuclei, which depends on the strength of the static magnetic field, the chemical environment, and the magnetic properties of the isotope involved.

NMR results from specific magnetic properties of certain atomic nuclei. Nuclear magnetic resonance spectroscopy is widely used to determine the structure of organic molecules in solution and study molecular physics and crystals as well as non-crystalline materials. See—Wikipedia.org.

The permanent magnets of production line NMR units differ from each other by resolution. Production line differ from highly expensive (for example cost of 200000 USD and above) laboratory NMR units.

There is a growing need to align the NMR measurements generated by different NMR systems.

### BRIEF DESCRIPTION OF THE DRAWINGS

The subject matter that is regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawing in which:

FIG. 1 illustrates an example of a method;

FIG. 2 illustrates an example of a method;

FIG. 3 illustrates an example of a process;

FIG. 4 illustrates an example of NMR units of a group; and

FIG. 5 illustrates examples of NMR spectrums.

### DETAILED DESCRIPTION OF THE DRAWINGS

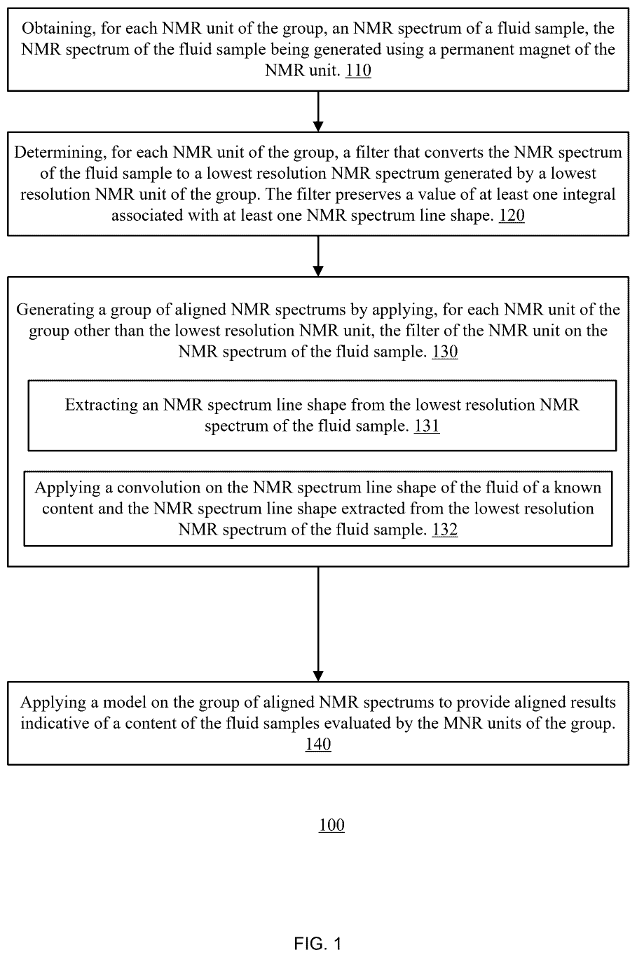

FIG. 1 illustrates an example of method 100 that is computer implemented and is for generating aligned nuclear magnetic resonance (NMR) results from a group of NMR units. The NMR units are production line NMR units.

According to an embodiment, method 100 includes step 110 of obtaining, for each NMR unit of the group, an NMR spectrum of a fluid sample, the NMR spectrum of the fluid sample being generated using a permanent magnet of the NMR unit.

According to an embodiment, step 110 includes performing, by each NMR unit of the group, an NMR measurement to provide the NMR spectrum NMR spectrum of the fluid sample, wherein different NMR units of the group receive different sample of the same fluid.

According to an embodiment, step 110 includes receiving (for example from a data structure) the NMR measurements.

According to an embodiment, step 110 is followed by step 120 of determining, for each NMR unit of the group, a filter that converts the NMR spectrum of the fluid sample to a lowest resolution NMR spectrum generated by a lowest resolution NMR unit of the group. The filter preserves a value of at least one integral associated with at least one NMR spectrum line shape.

The line shape is a portion of the spectrum and the integral associated with a line shape is an integral taken between the x-axis and the line shape—which provides an indication about an “area” below the line shape.

The preservation of the value increases the accuracy of the process and allows to align between NMR spectrums obtained by different NMR units.

It has been found that non-linear transformations (for example exponent based transformation used to transform low resolution NMR spectrums to higher resolution NMR spectrums introduce significant errors that dramatically prevent an accurate alignment between NMR units).

According to an embodiment, for each NMR unit of the group—the filter is calculated based on (i) an NMR spectrum line shape of a sample of a fluid of a known content (for example water or any other known content) obtained from the lowest resolution NMR unit, and (ii) a lowest resolution NMR spectrum of the fluid sample—especially an NMR spectrum line shape of the fluid sample.

According to an embodiment, step 120 is followed by step 130 of generating a group of aligned NMR spectrums by applying, for each NMR unit of the group other than the lowest resolution NMR unit, the filter of the NMR unit on the NMR spectrum of the fluid sample.

According to an embodiment, a generating of an aligned MNR spectrum by an NMR unit of the group includes:
a. Extracting an NMR spectrum line shape from the lowest resolution NMR spectrum of the fluid sample. (Step 131)
b. Applying a convolution on an inverted NMR spectrum line shape of the sample of the fluid of the known content and the NMR spectrum line shape extracted from the lowest resolution NMR spectrum of the fluid sample (Step 132) to provide a filter.
c. Applying the filter (by convolution) on an NMR spectrum of the fluid sample to provide an aligned NMR spectrum.

According to an embodiment, step 130 is followed by step 140 of applying a model on the group of aligned NMR spectrums to provide aligned results indicative of a content of the fluid samples evaluated by the MNR units of the group.

According to an embodiment, the model is a machine learning model.

According to an embodiment, the model is a chemometric model.

Once aligned, a single model may be applied on all the aligned NMR spectrums —which save significant computational and/or memory resources, does not require do develop different models to different NMR units, does not require to store different models for different NMR units, and may increase the reliability of the model—as the model may be trained and/or verified with more samples.

According to an embodiment, the resolutions of the NMR units of the groups are evaluated from time to time and a change in a resolution of at least one NMR unit is followed by a response—such as updating a filter of one or more NMR units, determining that at least one NMR unit is not fit, ignoring measurements from one or more NMR units, finding a new lowest resolution NMR unit, and the like.

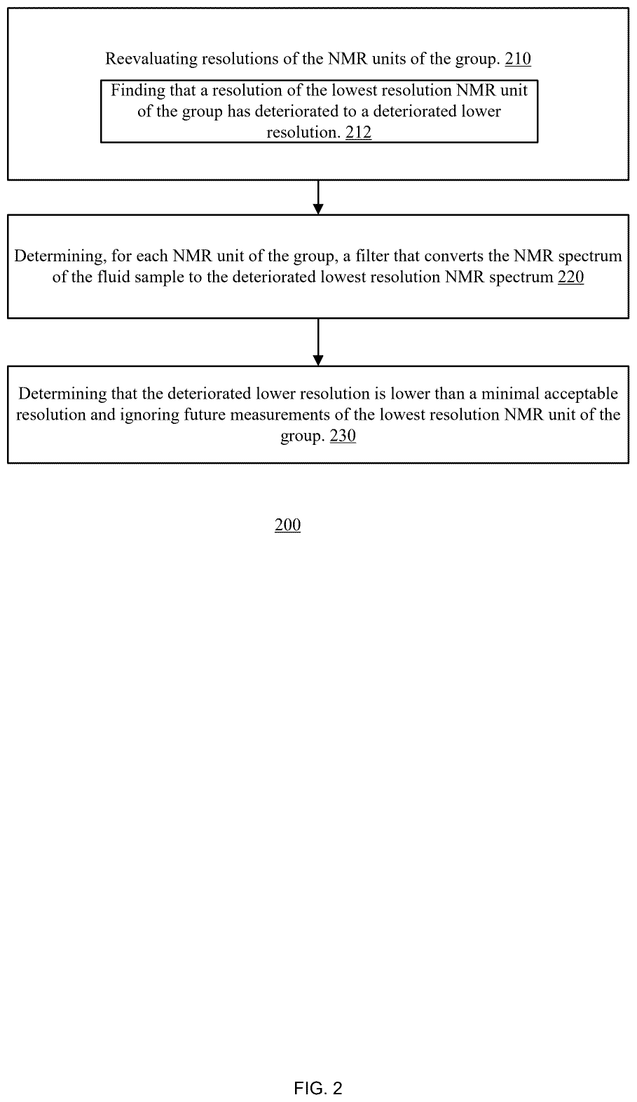

FIG. 2 illustrates an example of method 200 that is computer implemented and is for evaluation of resolutions.

Method 200 includes step 210 of reevaluating resolutions of the NMR units of the group.

According to an embodiment, step 210 includes step 212 of finding that a resolution of the lowest resolution NMR unit of the group has deteriorated to a deteriorated lower resolution.

According to an embodiment, step 212 is followed by step 220 of determining, for each NMR unit of the group, a filter that converts the NMR spectrum of the fluid sample to the deteriorated lowest resolution NMR spectrum.

According to an embodiment, step 212 is followed by step 230 of determining that the deteriorated lower resolution is lower than a minimal acceptable resolution and ignoring future measurements of the lowest resolution NMR unit of the group.

According to an embodiment, when finding that there is any change in the resolution of any of the NMR units—method 200 includes responding to the change—for example by amending the filter or that unit and optionally of another unit (for example when a new NMR unit becomes a new lowest resolution NMR unit—which requires to update the filters of the other NMR units of the group.

Method 100 and method 200 may be executed multiple times. A change in resolution found in method 200 may require to update at least one filter used during method 200.

Method 100 and method 200 are computer implemented and may be executed, at least in part, by one or more NMR units of the group and/or may be executed, at least in part, by a computerized system other than the NMR units.

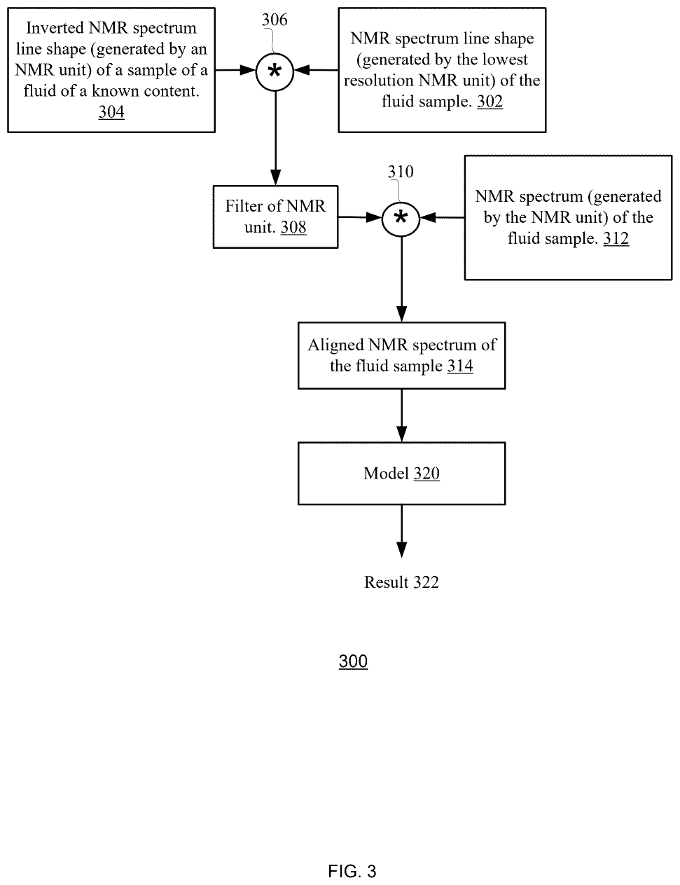

FIG. 3 illustrates an example an alignment process that includes:
a. Applying a convolution on (a) an NMR spectrum line shape (generated by the lowest resolution NMR unit) of the fluid sample 302 and (b) an inverted NMR spectrum line shape (generated by an NMR unit) of a sample of a fluid of a known content 304 to provide a filter 308 of the NMR unit.
b. Applying the filter 308 (by convolution) on NMR spectrum (generated by the NMR unit) of the fluid sample 312 to provide an aligned NMR spectrum of the fluid sample 314.
c. Applying model 320 on the aligned NMR spectrum of the fluid sample 314 to provide a result 322.

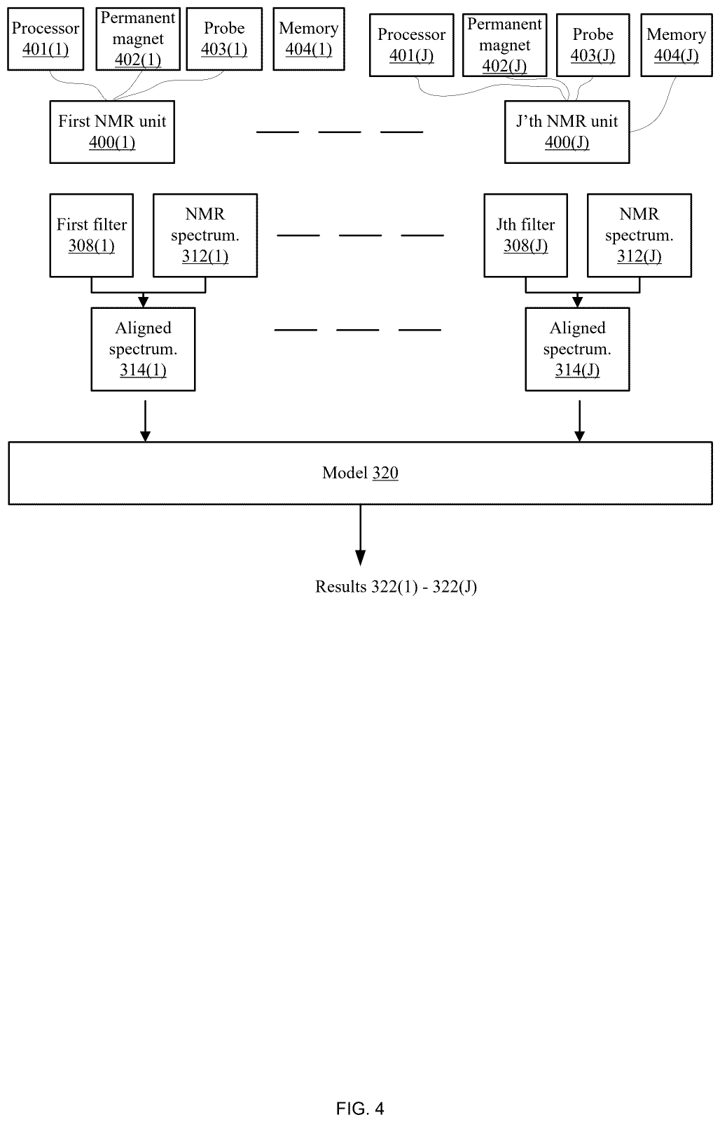

FIG. 4 illustrates an example of NMR units 400(1)-400(J) whereas J is an integer that exceeds one.

One of the J NMR units is currently a lowest resolution NMR unit. First NMR unit 400(1) includes processor 401(1), permanent magnet 402(1), probe 403(1), and memory 404(1). J'th NMR unit 400(J) includes processor 401(J), permanent magnet 402(J), probe 403(J), and memory 404(J).

First filter 308(1) of first NMR unit 400(1) is applied on NMR spectrum 312(1) of a sample fluid obtained by first NMR unit 400(1) to provide aligned spectrum 314(1).

Jth filter 308(J) of Jth NMR unit 400(J) is applied on NMR spectrum 312(J) of a sample fluid obtained by Jth NMR unit 400(J) to provide aligned spectrum 314(J).

Model 320 is applied on aligned spectrum 314(1) till aligned spectrum 314(J) to provide results 322(1)-322(J).

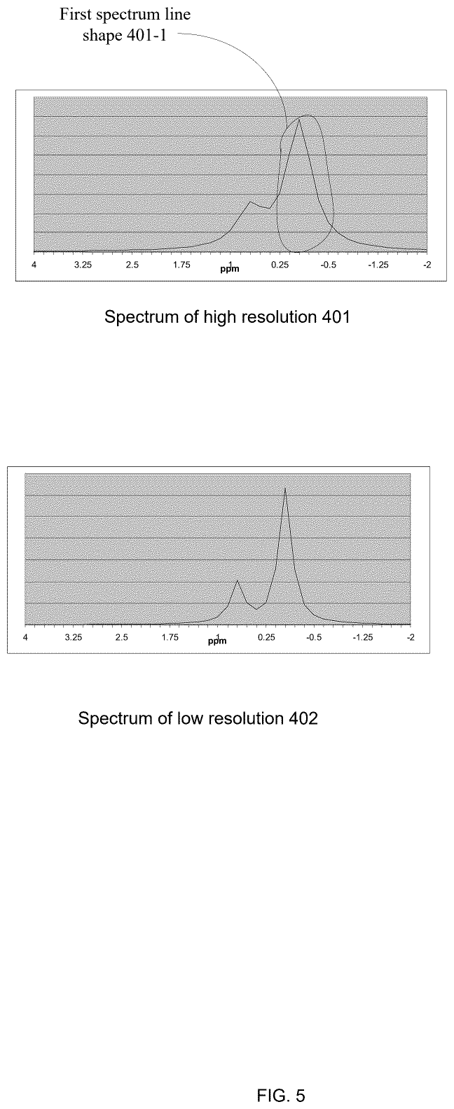

FIG. 5 illustrates an example of a spectrum of high resolution 401 and a spectrum of low resolution 402 and also illustrates a first spectrum line shape 401-1.

In the foregoing detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using microelectronics and/or optical components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method.

Any reference in the specification to a system should be applied mutatis mutandis to a method that may be executed by the system.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A method for generating aligned nuclear magnetic resonance (NMR) results from a group of NMR units, the method comprising:
obtaining, for each NMR unit of the group, an NMR spectrum of a fluid sample, the NMR spectrum of the fluid sample being generated using a permanent magnet of the NMR unit;
determining, for each NMR unit of the group, a filter that converts the NMR spectrum of the fluid sample to a lowest resolution NMR spectrum generated by a lowest resolution NMR unit of the group; wherein the filters preserves a value of at least one integral associated with at least one NMR spectrum line shape; wherein a filter of a given NMR unit of the group is calculated based on (i) a NMR spectrum line shape of a sample of a fluid of a known content obtained from the lowest resolution NMR unit, and (ii) a lowest resolution NMR spectrum of the fluid sample;
generating a group of aligned NMR spectrums by applying, for each NMR unit of the group other than the lowest resolution NMR unit, the filter of the NMR unit on the NMR spectrum of the fluid sample; and
applying a model on the group of aligned NMR spectrums to provide aligned results indicative of a content of the fluid samples evaluated by the MNR units of the group.

2. The method according to claim 1, wherein the filter is a linear filter.

3. The method according to claim 1, comprising:
extracting an NMR spectrum line shape from the lowest resolution NMR spectrum of the fluid sample, and
applying a convolution on the NMR spectrum line shape of the sample of the fluid of the known content and the NMR spectrum line shape extracted from the lowest resolution NMR spectrum of the reference sample.

4. The method according to claim 1, wherein the model is a machine learning model.

5. The method according to claim 1, wherein the model is a chemometric model.

6. The method according to claim 1, wherein the obtaining comprises performing, by each NMR unit of the group, an NMR measurement to provide the NMR spectrum NMR spectrum of the fluid sample, wherein different NMR units of the group receive different sample of the same fluid.

7. The method according to claim 1, comprising reevaluating resolutions of the NMR units of the group.

8. The method according to claim 7, comprising finding that a resolution of the lowest resolution NMR unit of the group has deteriorated to a deteriorated lower resolution.

9. The method according to claim 8, comprising determining, for each NMR unit of the group, a filter that converts the NMR spectrum of the fluid sample to the deteriorated lowest resolution NMR spectrum.

10. The method according to claim 8, comprising determining that the deteriorated lower resolution is lower than a minimal acceptable resolution and ignoring future measurements of the lowest resolution NMR unit of the group.

11. A non-transitory computer readable medium for generating aligned nuclear magnetic resonance (NMR) results from a group of NMR units, the non-transitory computer readable medium stores instructions executable by a processor for:
obtaining, for each NMR unit of the group, an NMR spectrum of a fluid sample, the NMR spectrum of the fluid sample being generated using a permanent magnet of the NMR unit;
determining, for each NMR unit of the group, a filter that converts the NMR spectrum of the fluid sample to a lowest resolution NMR spectrum generated by a lowest resolution NMR unit of the group; wherein the filters preserves a value of at least one integral associated with at least one NMR spectrum unit line; wherein a filter of a given NMR unit of the group is calculated based on (i) a NMR spectrum line shape of a sample of a fluid of a known content obtained from the lowest resolution NME unit, and (ii) a lowest resolution NMR spectrum of the fluid sample;
generating a group of aligned NMR spectrums by applying, for each NMR unit of the group other than the lowest resolution NMR unit, the filter of the NMR unit on the NMR spectrum of the fluid sample; and
applying a model on the group of aligned NMR spectrums to provide aligned results indicative of a content of the fluid samples evaluated by the MNR units of the group.

12. The non-transitory computer readable medium according to claim 6, wherein the filter is a linear filter.

13. The non-transitory computer readable medium according to claim 6, that stores instructions executable by a processor for:
extracting a NMR spectrum line shape from the lowest resolution NMR spectrum of the fluid sample, and
applying a convolution on the NMR spectrum line shape of the sample of a fluid of the known content and the NMR spectrum line shape extracted from the lowest resolution NMR spectrum of the fluid sample.

14. The non-transitory computer readable medium according to claim 6, wherein the model is a machine learning model.

15. The non-transitory computer readable medium according to claim 16, wherein the model is a chemometric model.

16. The non-transitory computer readable medium according to claim 11, wherein the obtaining comprises performing, by each NMR unit of the group, an NMR measurement to provide the NMR spectrum NMR spectrum of the fluid sample, wherein different NMR units of the group receive different sample of the same fluid.

17. The non-transitory computer readable medium according to claim 11, that stores instructions executable by a processor for reevaluating resolutions of the NMR units of the group.

18. The non-transitory computer readable medium according to claim 17, that stores instructions executable by a processor for finding that a resolution of the lowest resolution NMR unit of the group has deteriorated to a deteriorated lower resolution.

19. The non-transitory computer readable medium according to claim 18, that stores instructions executable by a processor for determining, for each NMR unit of the group, a filter that converts the NMR spectrum of the fluid sample to the deteriorated lowest resolution NMR spectrum.

20. The non-transitory computer readable medium according to claim 18, that stores instructions executable by a processor for determining that the deteriorated lower resolution is lower than a minimal acceptable resolution and ignoring future measurements of the lowest resolution NMR unit of the group.
